(19) United States
(12) Patent Application Publication
(10) Pub. No.: US 2024/0188376 A1
(43) Pub. Date: Jun. 6, 2024

(54) SUPPORT MEMBER, DISPLAY MODULE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Xiangdong WEI, Beijing (CN); Xiaoxia LIU, Beijing (CN); Xiaodong HAO, Beijing (CN); Danyang BI, Beijing (CN); Wei CHEN, Beijing (CN); Wei GONG, Beijing (CN); Yi ZHANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/279,389

(22) PCT Filed: Nov. 10, 2021
(86) PCT No.: PCT/CN2021/129889

§ 371 Date: Aug. 30, 2023

(30) Foreign Application Priority Data
Mar. 18, 2021 (CN) 202110292558.1

(51) Int. Cl. H10K 59/80; H10K 102/00

(52) U.S. Cl. CPC H10K 59/80; H10K 2102/311

(57) ABSTRACT

A support member, a display module and a display device are provided. The support member is configured for supporting a display panel and includes: a first support plate, being a flexible plate, the first support plate includes a first deformable region defined with a plurality of openings; a first adhesive layer, arranged on a side of the first support plate; and a second support plate, bonded to the side of the first support plate through the first adhesive layer, where a rigidity of the second support plate is greater than a rigidity of the first support plate, and the second support plate includes a second deformable region fitted and fixed with the first deformable region and corresponds to the bending region of the display panel.

### CROSS-REFERENCE TO RELATED APPLICATIONS

The present disclosure is a U.S. National Stage of International Application No. PCT/CN2021/129889, filed on Nov. 10, 2021, which claims a priority to Chinese Patent Application No. 202110292558.1, entitled “SUPPORT MEMBER, DISPLAY MODULE AND DISPLAY DEVICE”, filed on Mar. 18, 2021, the entire content of each is incorporated herein by reference.

### TECHNICAL FIELD

The present disclosure relates to a field of display technology, and more particularly, to a support member, a display module and a display device.

### BACKGROUND

With the development of technology, innovative products based on flexible OLED display modules, such as full-screen phones, foldable phones, and scrollable phones, have been widely loved and praised by people, and have enormous development potential and supply markets.

A back face of the OLED display panel is designed with a support member for supporting and strengthening the panel. However, with the development of various new flexible products, in addition to ensuring good support, the support member also needs to match shape of the flexible product, so as to improve a product yield and a success rate of the product development.

### SUMMARY

The purpose of the present disclosure is to overcome above deficiencies of the related art and provide a support member, a display module and a display device.

According to an aspect of the present disclosure, a support member is provided for supporting a display panel, and the support member includes:

a first support plate, being a flexible plate, where the first support plate includes a first deformable region defined with a plurality of openings;

a first adhesive layer, arranged on a side of the first support plate; and

a second support plate, bonded to the side of the first support plate through the first adhesive layer, where a rigidity of the second support plate is greater than a rigidity of the first support plate, and the second support plate includes a second deformable region fitted and fixed with the first deformable region.

In an exemplary embodiment of the present disclosure, the first deformable region is located at an edge of the first support plate.

In an exemplary embodiment of the present disclosure, the opening runs through the first support plate.

In an exemplary embodiment of the present disclosure, the first deformable region is bendable along a first direction; the opening includes a strip-shaped opening extending along the first direction, a plurality of strip-shaped openings are spaced apart from each other along a second direction, and the first direction and the second direction are intersected.

In an exemplary embodiment of the present disclosure, the opening is a blind hole defined on the first support plate, and the blind hole is located on a surface of the first support plate facing towards or away from the display panel.

In an exemplary embodiment of the present disclosure, both the first support plate and the second support plate are metal plates.

In an exemplary embodiment of the present disclosure, a thickness of the second support plate is greater than a thickness of the first support plate.

In an exemplary embodiment of the present disclosure, the thickness of the first support plate is less than or equal to 50 μm, and the thickness of the second support plate is greater than or equal to 100 μm.

According to another aspect of the present disclosure, a display module is provided and includes:

a display panel having a light-emitting side and a backlight side, where the display panel includes a planar region and a bending region;

a second adhesive layer, arranged on the backlight side of the display panel; and

the above support member, where the first support plate in the support member is bonded to the backlight side of the display panel through the second adhesive layer, and the first deformable region of the first support plate is fitted with the bending region of the display panel.

In an exemplary embodiment of the present disclosure, the first adhesive layer and the second adhesive layer are bonded as a whole at the openings of the first support plate.

In an exemplary embodiment of the present disclosure, the bending region is at least located on a side of the planar region.

According to yet another aspect of the present disclosure, a display device is provided and includes the above display module.

According to yet another aspect of the present disclosure, a display device is provided and includes the above display module.

The support member for supporting the display panel of the present disclosure is provided with a double-layer support plate, the first support plate is flexible and is defined with the openings, and the second support plate has rigidity and plays a major supporting role. The double-layer support plate may improve the support effect and the openings defined on the first deformable region of the first support plate are able to decompose the resilient force generated by the overall deformation of the double-layer support plate, so as to prevent occurrence of delamination between the two support plates, prevent occurrence of delamination between the support member and the display panel, further improves the structural stability of the bending region, and thereby improve the product production and the product yield.

It should be understood that the preceding general description and the following detailed description are exemplary and explanatory only and are not restrictive of the present disclosure.

### BRIEF DESCRIPTION OF THE DRAWINGS

The accompanying drawings here are incorporated in the specification and constitute a part of this specification, show embodiments in accordance with the present disclosure and serve to explain the principles of the present disclosure together with the specification. Obviously, the drawings in the following description are only some embodiments of the present disclosure, and for those ordinary skills in the art, other drawings may also be obtained from these drawings without creative efforts.

FIG. 1 is a top view of a display module according to an embodiment of the present disclosure;

FIG. 2 is a sectional schematic view along A-A direction in FIG. 1;

FIG. 3 is an enlarged schematic view of P region in FIG. 2;

FIG. 4 is a top view of another display module according to an embodiment of the present disclosure;

FIG. 5 is a sectional schematic view along B-B direction in FIG. 4;

FIG. 6 is another schematic view of an opening shape of the disclosed embodiment.

Reference numerals: 1, display panel; 11, planar region; 12, bending region; 2, first support plate; 21, first deformable region; 22, first planar region; 3, second support plate; 31, second deformable region; 32, second planar region; 4, opening; 5, first adhesive layer; 6, second adhesive layer.

### DETAILED DESCRIPTION

Example embodiments will now be described more fully with reference to the accompanying drawings. However, the embodiments can be implemented in a variety of forms and should not be construed as being limited to the examples set forth herein. Rather, these embodiments are provided so that the present disclosure will be more complete so as to convey the idea of the exemplary embodiments to those skilled in this art. The same reference numerals in the drawings denote the same or similar parts, and the repeated description thereof will be omitted. In addition, the drawings are merely schematic representations of the present disclosure and are not necessarily drawn to scale.

Although the relative terms such as “above” and “below” are used in the specification to describe the relative relationship of one component to another component shown, these terms are only for convenience in this specification, for example, according to an exemplary direction shown in the drawings. It should be understood that if the device shown is flipped upside down, the component described as “above” will become a component “below” another component. When a structure is “on” another structure, it may mean that a structure is integrally formed on another structure, or that a structure is “directly” disposed on another structure, or that a structure is “indirectly” disposed on another structure through other structures.

The terms “one,” “a,” “the,” and “said” are used to indicate that there are one or more elements, components, or the like. The terms “include” and “have” are used to indicate an open meaning of including and means that there may be additional elements, components, and the like, in addition to the listed elements, components, and the like. The terms “first,” “second,” and the like are used only as reference markers, and do not limit the number of objects.

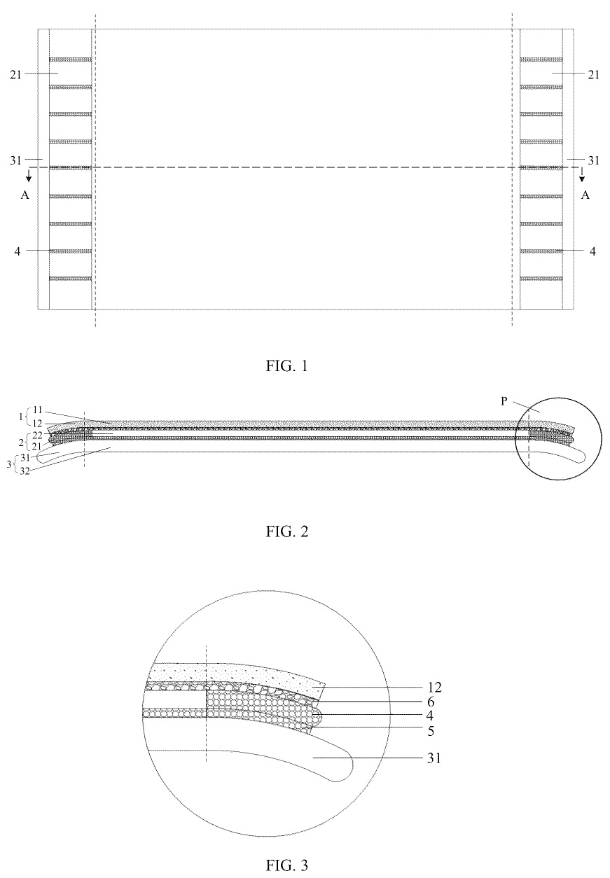

FIG. 1 is a top view of a display module including a support member provided by an embodiment of the present disclosure, and FIG. 2 is a sectional schematic view along A-A direction in FIG. 1; FIG. 3 is an enlarged schematic view of P region in FIG. 2. Referring to FIGS. 1 to 3, the display module includes a display panel 1 having a light-emitting side and a backlight side, as well as a support member. The support member is located on the backlight side of the display panel 1. The display panel 1 includes a planar region 11 and a bending region 12, which are distinguished by dashed lines in the drawings.

The support member includes a first support plate 2, a first adhesive layer 5, and a second support plate 3. The second support plate 3 is bonded to a side of the first support plate 2 through the first adhesive layer 5. The first support plate 2 is a flexible plate, and the first support plate 2 includes a first deformable region 21. The first deformable region 21 is defined with a plurality of openings 4. A shape of the first deformable region 21 matches a shape of the bending region 12 of the display panel 1, the first deformable region 21 and the bending region 12 are fitted and fixed together through the first adhesive layer 5. The second support plate 3 is arranged on a side of the first support plate 2 away from the display panel 1. A rigidity of the second support plate 3 is greater than that of the first support plate 2, which means that the second support plate 3 is less prone to bending compared to the first support plate 2. The second support plate 3 includes a second deformable region 31, which is fitted and fixed with the first deformable region 21 through the first adhesive layer 5.

Referring to FIG. 1, the first support plate 2 may further include a first planar region 22. Since the first support plate 2 is the flexible plate, the first planar region 22 only refers to being in a planar form during use and is able to be bent in practice. The second support plate 3 may further include a second planar region 32. Due to a relatively high rigidity of the second support plate 3, the second planar region 32 refers to being in a planar form during use or without external force.

It should be noted that the first support plate 2 is the flexible plate. When the bending region 12 of the display panel is in the bending process, the first deformable region 21 of the first support plate 2 may correspondingly change its form. For example, the bending region 12 of the display panel may have a flattened state, where the bending region 12 and the planar region 11 are located in the same plane, the first support plate 2 also forms a flat-plate structure as a whole, i.e., the first deformable region 21 of the display panel is also in a flat-plate shape. The bending region 12 of the display panel may also have a bending state, such as extending along a curve, where the bending region 12 and the planar region 11 are located in different planes. Correspondingly, the first deformable region 21 of the first support plate 2 also extends along a curve in a bending shape. The second support plate 3 is more rigid and less prone to bending compared to the first support plate 2, which means that it may maintain a more stable form (planar surface or curved surface) during use, thereby ensuring the stable support for the display panel 1. The second deformable region 31 of the second support plate 3 is formed through mechanical processing, so the second deformable region 31 is not completely incapable of bending and is actually bendable under a relatively great external force. Thus, the second deformable region 31 may be formed through the mechanical processing, such as stamping.

The support member is provided with a double-layer support plate, and the second support plate 3 has rigidity and plays a major supporting role for the display panel. The first support plate 2 is flexible and is arranged between the second support plate 3 and the display panel 1. The first support plate 2 may be bent to form a curved-surface form, which plays a certain supporting role for the bending region 12 of the display panel, and an overall structure of the double-layer support plate bonded as a whole may improve the support effect. Due to a relatively high rigidity of the second support plate 3, a resilient force is relatively great when the second support plate 3 is being bent, the openings defined on the first deformable region 21 of the first support plate 2 may release an overall deformation stress of the double-layer support plate, and the resilient force generated by an overall deformation of the double-layer support plate is decomposed, such that the overall resilient force of the double-layer support plate is reduced, so as to prevent occurrence of delamination between the first support plate 2 and the second support plate 3 due to the resilience of the first support plate 2, improve the structural stability of the bending region 12, and thereby improve the product production and the product yield.

In the present disclosure, the first support plate 2 and the second support plate 3 are bonded together through the first adhesive layer 5. The first adhesive layer 5 may be an adhesive material such as an optical adhesive. It may be understood that the adhesive material of the first adhesive layer 5 is bendable, so as to be bent in conjunction with the first support plate 2 and the second support plate 3.

Both the first support plate 2 and the second support plate 3 may be metal plates, such as stainless steel plates. The first support plate 2 is provided with a relatively thin thickness so as to be able to be bent, while the second support plate 3 is provided with a relatively thick thickness and is more rigid. In an embodiment, the thickness of the first support plate 2 is less than or equal to 50 μm. Furthermore, the thickness of the first support plate 2 is 30 μm<h<50 μm, and the first support plate 2 within this range may meet the requirement of both support strength and bending performance. In an embodiment, the thickness of the second support plate 3 is greater than or equal to 100 μm. Furthermore, the thickness of the second support plate 3 is 100 μm<h<300 μm, and the second support plate 3 within this range may meet the requirement of both the support strength and the overall module thickness.

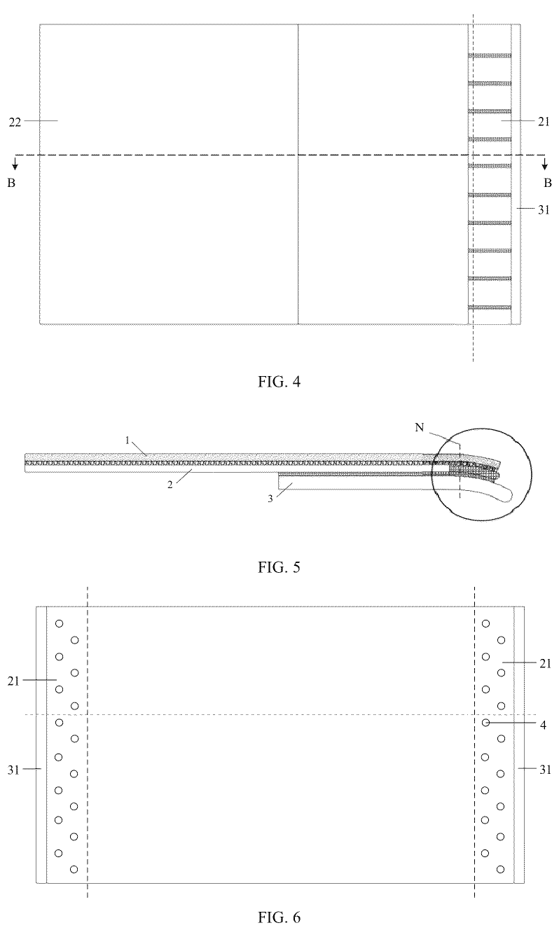

In the present disclosure, a position of the first deformable region 21 at the first support plate 2 and a position of the second deformable region 31 at the second support plate 3 are determined according to a position of the bending region 12 in the display panel 1. The bending region 12 of the display panel 1 may be located at at least a side of the planar region 11. Referring to FIG. 1, it is a bi-directional curved-surface display panel 1, and that is, a central display part of the display panel 1 is an entire planar region 11 with one bending region 12 provided on each of the left and right sides. For example, the bending region 12 is bent along a first direction in the drawing, i.e., a horizontal direction in the drawing. Correspondingly, a central part of the first support plate 2 is the first planar region 22, and the first deformable region 21 is located on the left and right sides of the first planar region 22; a central part of the second support plate 3 is the second planar region 32, and the second deformable region 31 is located on the left and right sides of the second planar region 32. Bending directions of the first deformable region and the second deformable region are consistent with a bending direction of the bending region 12. Referring to FIG. 4, it is a top view of a unidirectional curved-surface display panel 1, and FIG. 5 is a sectional schematic view along B-B direction in FIG. 4. An enlarged view of N region in FIG. 5 also refers to FIG. 3. A central display part of the display panel 1 is an entire planar region 11 with one bending region 12 provided on a right side. Correspondingly, a central part of the first support plate 2 is the first planar region 22, and the first deformable region 21 is located on the right side of the first planar region 22. A central part of the second support plate 3 is the second planar region 32, and the second deformable region 31 is located on the right side of the second planar region 32. In the display panels 1 shown in FIGS. 1 and 4, the bending region 12 is located at the edge of the display panel 1, and the first deformable region 21 and the second deformable region 31 are located at the edges of the first planar region 22 and the second planar region 32, respectively. The display panel 1 may be a curved-surface display panel or a flexible display panel with a curved-surface region such as a sliding roll or a scroll and the like. In another embodiment, the bending region 12 may also be located around the planar region 11. In an embodiment, the display panel 1 may also be a foldable display panel 1, which may include a plurality of planar regions 11, and the bending region 12 is arranged between adjacent planar regions 11 for folding. Correspondingly, the first support plate 2 and the second support plate 3 may further include a plurality of first planar regions 22, a plurality of second planar regions 32, respectively, and a first deformable region 21 and a second deformable region 31 are arranged between adjacent first planar regions 22, and between adjacent second planar regions 32, respectively. In summary, regardless of where the bending region 12 is located on the display panel 1, the support plate may be arranged with a curved-surface region at a corresponding position, and the support effect of the flexible display panel 1 may be improved through the double-layer structure while the bending region 12 of the display panel is prevented from separating from the second support plate 3 due to its high resilience, thereby improving the product production and the product yield.

As shown in FIGS. 2 to 4, in the present disclosure, the opening 4 on the first support plate 2 is a through hole running through the first support plate 2. Thus, the first adhesive layer 5 between the first support plate 2 and the second adhesive layer 6 overflows upwardly at the opening 4, and may further be bonded onto the display panel 1, such that the connection between the display panel 1 and the second support plate 3 is more secure and the occurrence of the delamination is prevented. Of course, in another embodiment, the opening 4 may also be a blind hole defined on an upper surface or a lower surface of the first support plate 2, and the first adhesive layer 5 or the second adhesive layer 6 may overflow at the opening 4 during the preparation process, and eventually “grasps” on the first support plate 2 or the second support plate 3, which may also improve the overall structural stability of the module bending part.

Referring to FIG. 6, the opening 4 includes a strip-shaped opening, and an extension direction of the strip-shaped opening is consistent with the bending directions of the first deformable region and the second deformable region, i.e., the strip-shaped opening extends along the first direction. The first direction is consistent with the bending direction of the bending region 12 of the display panel, i.e., the horizontal direction in the drawing. A plurality of strip-shaped openings are spaced apart from each other along a second direction, i.e., a longitudinal direction in the drawing. The strip-shaped openings in the horizontal direction may release a stress of the first deformable region 21 along the bending direction, so as to effectively release the stress.

In another embodiment, the opening 4 further includes a strip-shaped opening extending in the longitudinal direction, a plurality of strip-shaped openings extending in the longitudinal direction are spaced apart from each other along the horizontal direction, and the plurality of strip-shaped openings in two directions intersect in a grid shape (not shown in the drawings). The grid-shaped strip-shaped openings may release the stress of the first deformable region 21 along the bending direction and another direction simultaneously, which may provide a better release effect.

In other embodiments, a shape of the opening 4 includes, but is not limited to, a strip shape, and may also be any regular shape as shown in FIG. 6, such as a circular shape, a rectangular shape, a diamond shape, a hexagonal shape and the like, or an irregular shape. The plurality of openings 4 are arranged in an array at the first deformable region 21 of the first support plate 2, which may also release the stress of the first deformable region 21 evenly.

The present disclosure also provides a display module including the aforementioned support member, as shown in the drawing. The support member is arranged on a backlight side of the display panel 1, and the first deformable region 21 of the first support plate 2 is fitted with the bending region 12 of the display panel 1, to form the display module. A second adhesive layer 6 may be arranged between the first support plate 2 and the display panel 1 to bond the two together. The display panel 1, the first support plate 2 and the second support plate 3 are fitted with each other one by one and bonded together, due to the openings defined in the first deformable region 21 of the first support plate 2, the deformation stress of the double-layer support member and the display panel may be released, and the resilient force generated by the overall deformation of the double-layer support member and the display panel may be decomposed to reduce the resilient force between the double-layer support member and the display panel, so as to prevent the separation of the display panel 1 and the double-layer support member.

A material of the second adhesive layer 6 may be the same as or different from the that of the first adhesive layer 5. For example, the material of the second adhesive layer may be an adhesive material such as an optical adhesive. It may be understood that the material of the second adhesive layer 6 is also bendable, so as to be bent in conjunction with the display panel.

Since the opening 4 is defined on the first support plate 2, and the opening 4 is a through hole running through the first support plate 2, the first adhesive layer 5 overflows upwardly at the opening 4 during the production process and is bonded with the second adhesive layer 6 as a whole. The first adhesive layer 5 and the second adhesive layer 6 “wrap” the first support plate 2, which also improves the overall structural stability of the module bending part and prevent the occurrence of delamination between the display panel 1 and the support member. Similarly, when the second adhesive layer 6 is prepared, the second adhesive layer 6 also overflows downwardly at the opening 4 and is bonded with the first adhesive layer 5 as a whole.

As stated above, the display panel in the display module may be a curved-surface display panel or a flexible display panel with a curved-surface region such as a sliding roll or a scroll and the like. Based on the support of the support member, the disclosed display module may improve the product yield and a success rate of the product development, and also ensure a form of the flexible product to meet design requirements.

Embodiments of the present disclosure further provide a display device including the display module of the above-mentioned embodiments. Since the display device includes the above-mentioned display module, it has the same beneficial effects, and details are not described here in the present disclosure.

The present disclosure does not specifically limit the application of display devices, which may be any product or members having a flexible display function, such as, TV, notebook computer, tablet computer, wearable display device, mobile phone, in-vehicle display, navigation device, e-book, digital photo frame, advertising light box, and the like.

Those skilled in the art will easily think of other embodiments of the present disclosure after considering the specification and practicing the invention disclosed herein. The present disclosure is intended to cover any variations, uses, or adaptive changes of the present disclosure. These variations, uses, or adaptive changes follow the general principles of the present disclosure and include common knowledge or conventional technical means in the technical field that are not disclosed in the present disclosure. The description and embodiments are only regarded as exemplary, and the true scope and spirit of the present disclosure are defined by the appended claims.

1. A support member for supporting a display panel, comprising:
a first support plate, being a flexible plate, wherein the first support plate comprises a first deformable region defined with a plurality of openings:
a first adhesive layer, arranged on a side of the first support plate; and
a second support plate, bonded to the side of the first support plate through the first adhesive layer, wherein a rigidity of the second support plate is greater than a rigidity of the first support plate, and the second support plate comprises a second deformable region fitted and fixed with the first deformable region.

2. The support member according to claim 1, wherein the first deformable region is located at an edge of the first support plate.

3. The support member according to claim 2, wherein the opening runs through the first support plate.

4. The support member according to claim 3, wherein the first deformable region is bendable along a first direction: the opening comprises a strip-shaped opening extending along the first direction, a plurality of strip-shaped openings are spaced apart from each other along a second direction, and the first direction and the second direction are intersected.

5. The support member according to claim 1, wherein the opening is a blind hole defined on the first support plate, and the blind hole is located on a surface of the first support plate facing towards or away from the display panel.

6. The support member according to claim 1, wherein both the first support plate and the second support plate are metal plates.

7. The support member according to claim 6, wherein a thickness of the second support plate is greater than a thickness of the first support plate.

8. The support member according to claim 7, wherein the thickness of the first support plate is less than or equal to 50 μm, and the thickness of the second support plate is greater than or equal to 100 μm.

9-12. (canceled)

13. The support member according to claim 2, wherein the opening is a blind hole defined on the first support plate, and the blind hole is located on a surface of the first support plate facing towards or away from the display panel.

14. A display module, comprising:
a display panel having a light-emitting side and a backlight side, wherein the display panel comprises a planar region and a bending region:
a second adhesive layer, arranged on the backlight side of the display panel; and
a support member comprising:
a first support plate, being a flexible plate, wherein the first support plate comprises a first deformable region defined with a plurality of openings:
a first adhesive layer, arranged on a side of the first support plate; and
a second support plate, bonded to the side of the first support plate through the first adhesive layer, wherein a rigidity of the second support plate is greater than a rigidity of the first support plate, and the second support plate comprises a second deformable region fitted and fixed with the first deformable region:
wherein the first support plate in the support member is bonded to the backlight side of the display panel through the second adhesive layer, and the first deformable region of the first support plate is fitted with the bending region of the display panel.

15. The display module according to claim 14, wherein the first adhesive layer and the second adhesive layer are bonded as a whole at the openings of the first support plate.

16. The display module according to claim 14, wherein the bending region is at least located on a side of the planar region.

17. The display module according to claim 14, wherein the first deformable region is located at an edge of the first support plate.

18. The display module according to claim 17, wherein the opening runs through the first support plate.

19. The display module according to claim 18, wherein the first deformable region is bendable along a first direction: the opening comprises a strip-shaped opening extending along the first direction, a plurality of strip-shaped openings are spaced apart from each other along a second direction, and the first direction and the second direction are intersected.

20. The display module according to claim 14, wherein the opening is a blind hole defined on the first support plate, and the blind hole is located on a surface of the first support plate facing towards or away from the display panel.

21. The display module according to claim 14, wherein both the first support plate and the second support plate are metal plates.

22. The display module according to claim 21, wherein a thickness of the second support plate is greater than a thickness of the first support plate.

23. The display module according to claim 22, wherein the thickness of the first support plate is less than or equal to 50 μm, and the thickness of the second support plate is greater than or equal to 100 μm.

24. A display device, comprising a display module, wherein the display module comprises:
a display panel having a light-emitting side and a backlight side, wherein the display panel comprises a planar region and a bending region;
a second adhesive layer, arranged on the backlight side of the display panel; and
a support member comprising:
a first support plate, being a flexible plate, wherein the first support plate comprises a first deformable region defined with a plurality of openings;
a first adhesive layer, arranged on a side of the first support plate; and
a second support plate, bonded to the side of the first support plate through the first adhesive layer, wherein a rigidity of the second support plate is greater than a rigidity of the first support plate, and the second support plate comprises a second deformable region fitted and fixed with the first deformable region;
wherein the first support plate in the support member is bonded to the backlight side of the display panel through the second adhesive layer, and the first deformable region of the first support plate is fitted with the bending region of the display panel.
